(19) United States
(12) Patent Application Publication
(10) Pub. No.: US 2024/0162266 A1
(43) Pub. Date: May 16, 2024

(54) SIP MODULE

(71) Applicant: LG INNOTEK CO., LTD., Seoul (KR)

(72) Inventor: Byung Hyun CHOI, Seoul (KR)

(21) Appl. No.: 18/282,893

(22) PCT Filed: Apr. 19, 2022
(86) PCT No.: PCT/KR2022/005628

§ 371 Date: Sep. 19, 2023

(30) Foreign Application Priority Data
Apr. 21, 2021 (KR) 10-2021-0051972

(51) Int. Cl. H01L 27/146; H01L 23/00; H01L 23/36; H01L 23/498

(52) U.S. Cl. CPC H01L 27/14634; H01L 23/36; H01L 23/49822; H01L 24/16; H01L 24/32; H01L 24/73; H01L 2224/16225; H01L 2224/32225; H01L 2224/73204

(57) ABSTRACT

A SiP module according to the embodiment comprises: a substrate; an image sensor disposed on one surface of the substrate; and a serializer embedded inside the substrate. The substrate includes a via hole that penetrates through the substrate in order to electrically connect the image sensor and the serializer.

### TECHNICAL FIELD

The present invention relates to a SiP module, and more particularly, to a technology in which a serializer is embedded in a SiP module substrate.

### BACKGROUND ART

Advanced driver assistance system (ADAS) is one of the most rapidly growing fields among automotive applications. Owing to various functions, in addition to warning the driver and ensuring better visibility in the outside of the vehicle, parking assistance and adaptive cruise control and the like are also supported. These functions are realized by various measurement systems based on radar, camera, distance measurement using light, ultrasonic waves, and the like.

Implementation of the ADAS function using a camera may be performed by processing an image acquired from the camera. Accordingly, miniaturization of the camera module is required.

### DETAILED DESCRIPTION OF THE INVENTION

### Technical Subject

A technical subject to be solved by the present invention is to provide a system in package (SiP) module capable of simplifying an interface by modularizing an image sensor and a serializer that have been separated in the prior art.

The subjects of the present invention are not limited to the subjects mentioned above, and other subjects not mentioned will be clearly understood by those skilled in the art from the following description.

### Technical Solution

In order to solve the above technical subjects, a SiP module according to the present embodiment may comprise: a substrate; an image sensor being disposed on one surface of the substrate; and a serializer being embedded inside the substrate, wherein the substrate may include a via hole penetrating the substrate to electrically connect the image sensor and the serializer.

A resistor being embedded inside the substrate may be included.

A heat dissipation pad being disposed on the other surface of the substrate may be included, and the serializer may be disposed to be overlapped with the heat dissipation pad in an optical axis direction.

The substrate includes: a first layer on which the image sensor is disposed; a second layer in which the serializer is embedded; and a third layer on which the heat dissipation pad is disposed, wherein the second layer may be disposed between the first layer and the third layer.

An adhesive member may be applied to one surface and the other surface of the second layer.

The serializer may be any one among a low voltage differential signaling (LVDS), V-by-One HS, HD-Base-T, and MIPI A-PHY chip sets.

The image sensor is one image sensor among plurality types of image sensors, and a pin may be formed at a position corresponding to a connecting terminal configured with one pin map on one surface of the substrate.

A camera module according to the present embodiment may comprise: a first substrate; an image sensor being disposed on one surface of the first substrate; a serializer being embedded inside the substrate; and a second substrate being disposed with the first substrate on one surface thereof, wherein the first substrate may include a via hole penetrating the first substrate in order to electrically connect the image sensor and the serializer.

A power block and a connector may be disposed on the other surface of the second substrate.

### Advantageous Effects

According to the present embodiment, the internal structure of the camera can be miniaturized compared to the conventional design by embedding the serializer in substrate, and price competitiveness can be secured through the relaxation of the substrate specifications and the removal of the flexible substrate.

In addition, by modularizing the image sensor and serializer into a SiP module, the overall assembly process can be simplified because a separate image sensor reinforcement process is not required in the final camera assembly process.

In addition, even if the type of image sensor is different, it can be connected to the SiP module substrate configured with the same pin map, so that the SiP module can be transformed into a platform.

Effects according to the present invention are not limited by the contents exemplified above, and more various effects are included in the present specification.

### BRIEF DESCRIPTION OF DRAWINGS

FIG. 1 illustrates an internal substrate of a conventional vehicle camera.

FIG. 2 is a block diagram of a camera internal interface according to the present embodiment.

FIGS. 3 to 5 illustrate a SiP module according to the present embodiment.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or arranged in “on (above)” or “below (under)” of each component, “on (above)” or “below (under)” means that it includes not only the case where the two components are directly in contact with, but also the case where one or more other components are formed or arranged between the two components. In addition, when expressed as “on (above)” or “below (under)”, the meaning of not only an upward direction but also a downward direction based on one component may be included.

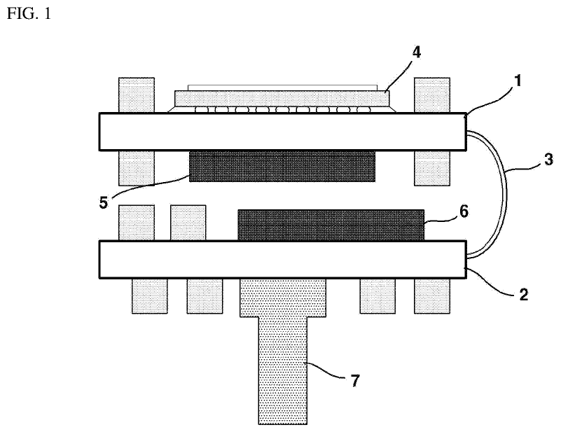

In general, a camera structure for a vehicle includes a serializer for high-speed transmission of video signals because the physical distance between a location where the camera is attached and a host is large. Hereinafter, with reference to FIG. 1, a conventional camera module internal substrate structure will be described.

An image sensor 4 is disposed on an upper surface of an upper substrate 1, a power block 5 is disposed on a lower surface, a serializer 6 is disposed on an upper surface of a lower substrate 2, and a connector 7 may be connected to a lower surface. In addition, additional electronic parts may be disposed on the upper substrate 1 and the lower substrate 2 in addition to the above parts. This is exemplary and is not particularly limited thereto.

The upper substrate 1 and the lower substrate 2 may be connected through a flexible substrate 3. Since the image sensor 4 and the serializer 6 have many signal connections, and the image signal received from the image sensor 4 must be transmitted to the serializer 6 at high speed, the image sensor 4 disposed on different substrates and the serializer 6 are electrically connected through the flexible substrate 3.

In such an internal structure of the camera module, there is a problem in that as the image sensor becomes highly pixelated, an increased number of connection pads and a high-spec PCB are required, and processes such as additional bonding are increased to enhance reliability due to the miniaturization of the camera.

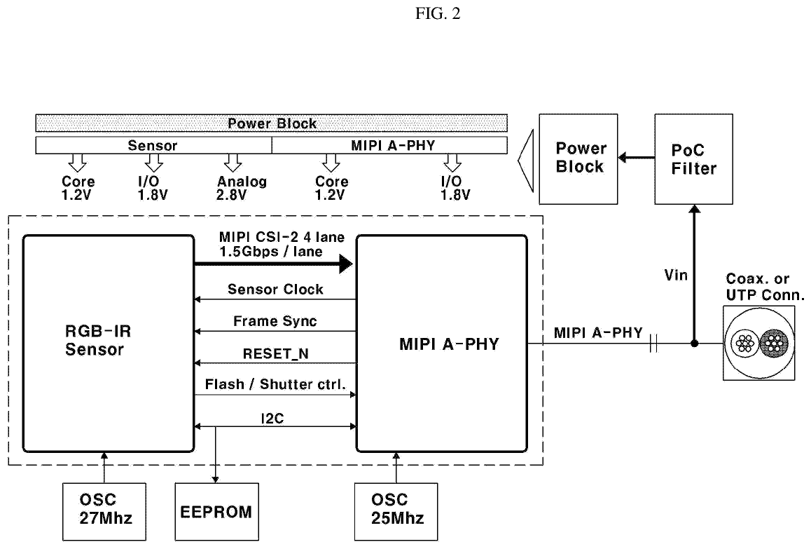

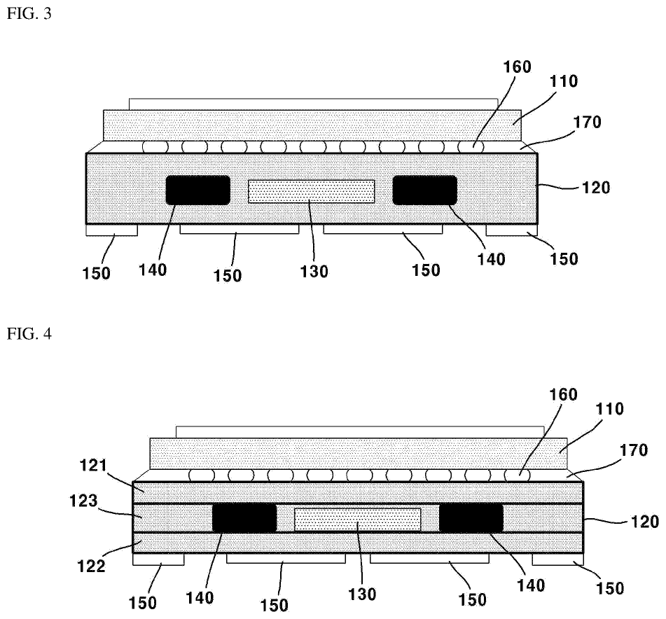

Hereinafter, the SiP module according to the present embodiment will be described with reference to FIGS. 2 to 5. FIG. 2 illustrates a block diagram of a camera internal interface according to the present embodiment. FIGS. 3 to 5 illustrate a SiP module according to the present embodiment.

The SiP module substrate according to the present embodiment may include a substrate 120 and a serializer 130, and the SiP module according to the present embodiment may include an image sensor 110, a substrate 120, and a serializer 130.

The substrate 120 may be a printed circuit board (PCB). The substrate 120 may be formed of a single layer. The substrate 120 may be formed of a plurality of layers.

An embedded serializer 130 may be included in the substrate 120. Unlike conventional bonding of electronic parts on the surface of a substrate through surface mounting technology (SMT), the “embedded technology” used in the present invention refers to a technology of inserting electronic parts into a substrate.

When the serializer 130 is embedded inside the substrate 120, the size of the substrate 120 can be reduced, and the connection length between other active and passive devices mounted inside the substrate 120 is shortened, so that the electrical performance can be improved by reducing the inductance component and the reliability of surface mounting of the substrate can be improved by reducing the number of soldering works for mounting.

Specifically, the serializer 130 may be embedded inside the substrate 120 and electrically connected to the image sensor 110. Although not shown, via hole (not shown) may be formed in the substrate 120 to electrically connect the image sensor 110 and the serializer 130. Referring to FIG. 3, the serializer 130 may be disposed to be embedded inside a substrate 120 formed of a single layer.

Referring to FIG. 4, when the substrate 120 is formed of a plurality of layers, the serializer 130 may be disposed between the pluralities of layers. The substrate 120 may include first to third layers 121, 122, and 123, and it is natural that the number of layers may be increased or decreased according to the number of parts to be mounted, and is not particularly limited thereto. The image sensor 110 may be disposed on an upper surface of the first layer 121, which is the top layer of the substrate 120. A heat dissipation pad 150 may be disposed on a lower surface of the third layer 122, which is a bottom layer of the substrate 120. The serializer 130 may be disposed in the second layer 123 positioned between the first layer 121 and the third layer 122. Although not shown, a plurality of electronic elements may be disposed on an upper surface of the first layer 121 or a lower surface of the third layer 122.

An adhesive member may be applied on one surface of a layer on which the serializer 130 is disposed among the pluralities of layers of the substrate 120. The adhesive member may be epoxy. This is to zero the air in the layer of the substrate 120 in which the serializer 130 is embedded so that thermal expansion does not occur. Among the plurality of layers of the substrate 120, a layer on which the serializer 130 is disposed may be molded so that the serializer 130 may be embedded therein.

A serializer, also referred to as a serial converter, is a configuration that converts various parallel signals into serial signals. Specifically, the serializer receives parallel data from a large number of pins, converts it into serial data, and outputs the data through a small number of pins, thereby possibly reducing the overall number of pins by allowing one pin to play multiple roles.

The serializer 130 may be any one among a low voltage differential signaling (LVDS), V-by-One HS, HD-Base-T, and MIPI A-PHY chip sets. The serializer 130 may be any one among a variety of communication interfaces. The serializer 130 may be in the form of a chip. The serializer 130 may be in the form of an element. The serializer 130 may be in the form of an electronic part.

Mobile industry processor interface (MIPI) is an interface specification defined by the MIPI Alliance established by Intel, ARM, Nokia, Samsung, ST, and TI to enhance reuse and compatibility in mobile and Internet of Things devices. The specifications set by MIPI include MIPI D-PHY, MIPI M-PHY, MIPI C-PHY, and the like. In particular, MIPI A-PHY can be used when data is transmitted at high speed between cameras and displays, and a related domain electronic control units (ECUs). MIPI A-PHY has high stability with low error rate, has high resilience with ultra-high level of tolerance even in automotive environment, can be used in long-distance communication range, and can improve data rate.

Referring to FIG. 2, RGB-IR Sensor, which is the image sensor 110, and MIPI A-PHY, which is one type of the serializer 130, communicates through a plurality of pins. Conventionally, the image sensor and the serializer are disposed in separate substrates, requiring a flexible substrate to connect each substrate. However, the SiP module according to the present embodiment disposes the image sensor on an upper surface of the substrate and the serializer is embedded inside the substrate, and the image sensor and serializer are electrically connected and modularized.

A resistor 140 being embedded inside the substrate 120 may be included.

Specifically, the resistor 140 may be connected to electronic parts being disposed inside the substrate 120. Electronic parts being mounted inside or on a surface of the substrate 120 may be connected to the resistor 140 being embedded inside the substrate 120 so that they can be terminated inside the substrate 120. Through this, it is possible to simplify the inside of the substrate 120 without the need to connect the electronic parts to the outside through wires.

The resistor 140 may be disposed adjacent to the serializer 130 being embedded in the substrate 120. The resistor 140 may include a plurality of resistors. When the substrate 120 is formed of a plurality of layers, the resistor 140 may be embedded in a layer in which the serializer 130 is embedded. Or, the resistor 140 may be embedded in a layer in which the serializer 130 is not embedded.

An image sensor 110 may be disposed on an upper surface of the substrate 120.

Specifically, the image sensor 110 may be electrically connected to the substrate 120. The image sensor 110 may be electrically connected to the serializer 130 embedded in the substrate 120. The image sensor may be coupled to the substrate 120 by surface mounting technology. The image sensor may be coupled to the substrate 120 by flip chip technology.

The image sensor 110 may be any one among a charge coupled device (CCD), a complementary metal oxide semiconductor (CMOS), a CPD, and a CID. The horizontal and/or vertical length of a unit pixel of the image sensor 110 may be 2 μm (micrometer) or less. It is not particularly limited thereto, and the overall size of the image sensor 110 may be increased as the number of pixels increases. Through this, it can be applied to a camera module with a high number of pixels and/or pixels.

Referring to FIG. 3, the image sensor 110 may be coupled to the substrate 120 using flip chip technology. Flip-chip technology is a method of wireless bonding, one of device mounting technologies, and is a technology to fuse as it is using lead bumps that serve as electrodes on the bottom side without using an additional connection structure such as a metal lead (wire) or an intermediate medium such as a ball grid array (BGA) when attaching a chip to a substrate. This technology has effects in that it is advantageous in miniaturization and light weight as the package is the same size as the chip, has excellent thermal stability and high current application rate, can increase the reaction speed, and can make the distance between electrodes much finer.

A bump 160 is formed on a lower surface of the image sensor 110 and can be bonded to the substrate 120 by fusion bonding. The bump 160 is bonded to the substrate 120 by compression or may be bonded by thermal compression. After the bump 160 of the image sensor 110 is fused to and coupled to an upper surface of the substrate 120, an adhesive member 170 may be additionally applied between the image sensor 110 and an upper surface of the substrate 120. An underfill may be applied between the image sensor 110 and an upper surface of the substrate 120. A certain space formed between the image sensor 110 and the substrate 120 can be filled by the bump 160 of the image sensor 110, and the mounting reliability of the image sensor 110 can be reinforced.

The substrate 120 may include at least one via hole penetrating the substrate 120. The serializer 130 may be electrically connected to the image sensor 110 being disposed in the substrate 120 through via hole. The resistor 140 and electronic parts may be electrically connected to each other through via holes.

The image sensor 110 may be one among a plurality of types of image sensors. For example, the type and size of the image sensor 110 may vary depending on the number of pixels. In general, as the area of the image sensor increases, a sharper resolution image can be obtained.

A pin may be formed on one surface of the substrate 120 at a position corresponding to a connection terminal configured with one pin map. It is possible to couple different image sensors by replacing them in the connection terminal configured with one pin map, and there is no need to separately manufacture a SiP module substrate for each type of image sensor. The SiP module for each pixel of the image sensor is configured with the same size and the same pin map so that the substrate of the camera module can be made into a platform.

A heat dissipation pad 150 may be disposed on the other surface of the substrate 120.

Specifically, the heat dissipation pad 150 may be a thermal conductive tape (thermal pad). The heat dissipation pad 150 has high thermal conductivity and can reduce heat generated inside the camera. The heat dissipation pad 150 may be in the form of a tape. The heat dissipation pad 150 may be in the form of a double-sided tape.

The serializer 130 may be disposed to be overlapped with the heat dissipation pad 150 in an optical axis direction. The serializer 130 may be disposed to be overlapped with the heat dissipation pad 150 in a direction perpendicular to the optical axis. Through this, heat being radiated from the serializer 130 can be more effectively discharged.

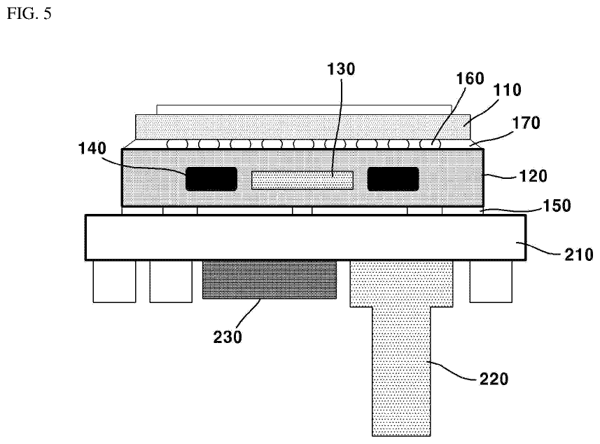

Next, referring to FIG. 5, the camera module including a SiP module according to the present embodiment will be described. The SiP module according to the present embodiment includes an image sensor 110, a first substrate 120, and a serializer 130, and a camera module according to the present embodiment may include an image sensor 110 and a first substrate 120, a serializer 130, and a second substrate 210. The detailed description of the camera module of the present invention corresponds to the detailed description of each part with reference to FIGS. 2 and 3, so overlapping descriptions will be omitted.

One surface of the second substrate 210 may be disposed on the first substrate 120 of the SiP module, and the power block 230 and the connector 220 may be disposed on the other surface of the second substrate 210. The first substrate 120 may be coupled to an upper surface of the second substrate 210 by the heat dissipation pad 150 being disposed on a lower surface of the first substrate 120. This is exemplary and is not particularly limited thereto.

The power block 230 may be coupled to the second substrate 210. The power block 230 may be a converter. The power block 230 may convert a level of power received from an external device (not shown) into a level of power required by the substrate, and a power having the converted level can be outputted to each electronic part. For example, the power block 230 may include at least one of a DC-DC converter (not shown) or a low voltage drop out (LDO) regulator (not shown).

The connector 220 may be coupled to the second substrate 210. The connector 220 may be electrically connected to the second board 210. The connector 220 may supply external power into the camera device. The connector 220 may include a port for electrical connection with an external device. The cross section of the connector 220 may be formed in a circular shape. Unlike this, the cross section of the connector 220 may be variously changed into an elliptical or rectangular shape and the like.

According to the present embodiment, the internal structure of the camera can be miniaturized compared to the conventional design by embedding the serializer in a substrate, so price competitiveness can be secured through the relaxation of the substrate specifications and the removal of the flexible substrate. In addition, by modularizing the image sensor and serializer SiP, the entire assembly process can be simplified as a separate image sensor reinforcement process is not required in the final camera assembly process. In addition, even if the type of image sensor is different, it can be connected to the SiP module substrate configured with the same pin map, so that the SiP module can be made into a platform.

Although the embodiments of the present invention have been described with reference to the accompanying drawings, those of ordinary skill in the art to which the present invention belongs will be able to understand that the present invention may be embodied in other specific forms without changing its technical spirit or essential features. Therefore, the embodiments described above should be understood as illustrative in all respects and not limiting.

### DESCRIPTION OF THE SYMBOLS

| | |
|---|---|
| 110: image sensor | 120: substrate |
| 130: serializer | 140: resistor |
| 150: heat dissipation pad | 160: solder ball |
| 170: adhesive member | 210: camera module substrate |
| 220: connector | 230: power block |

1. A SiP module comprising:
a substrate;
an image sensor being disposed on one surface of the substrate; and
a serializer being embedded inside the substrate,
wherein the substrate includes a via hole that penetrates through the substrate in order to electrically connect the image sensor and the serializer, and
wherein the serializer is disposed to be overlapped with the image sensor in a optical axis.

2. The SiP module according to claim 1, comprising:
a resistor being embedded inside the substrate.

3. The SiP module according to claim 1, comprising:
a heat dissipation pad being disposed in other surface of the substrate,
wherein the serializer is disposed to be overlapped with the heat dissipation pad in the optical axis direction.

4. The SiP module according to claim 3,
wherein the substrate comprises a first layer being disposed with the image sensor, a second layer being embedded with the serializer, and a third layer being disposed with the heat dissipation pad, and
wherein the second layer is disposed between the first layer and the third layer.

5-10. (canceled)

11. The SiP module according to claim 4, comprising:
a resistor being embedded inside the second layer of the substrate.

12. The SiP module according to claim 4,
wherein an adhesive member is applied to one surface and the other surface of the second layer.

13. The SiP module according to claim 1, comprising:
a bump being formed on a lower surface of the image sensor,
wherein the bump is bonded to the substrate.

14. The SiP module according to claim 13,
wherein an adhesive member is applied to a certain space formed between the image sensor and the substrate.

15. The SiP module according to claim 1,
wherein the serializer is any one among a low voltage differential signaling (LVDS), V-by-One HS, HD-Base-T, and MIPI A-PHY chip sets.

16. The SiP module according to claim 1,
wherein the image sensor is one image sensor among a plurality types of image sensors, and
wherein a pin is formed at a position corresponding to a connecting terminal configured with one pin map on one surface of the substrate.

17. A camera module comprising:
a first substrate;
an image sensor being disposed on one surface of the first substrate;
a serializer being embedded inside the first substrate; and
a second substrate being disposed with the first substrate on one surface thereof,
wherein the first substrate includes a via hole penetrating the first substrate in order to electrically connect the image sensor and the serializer, and
wherein the serializer is disposed to be overlapped with the image sensor in an optical axis.

18. The camera module according to claim 17,
a power block and a connector are disposed on the other surface of the second substrate.

19. The camera module according to claim 17, comprising:
a resistor being embedded inside the first substrate.

20. The camera module according to claim 17, comprising:
a heat dissipation pad being disposed between the first substrate and the second substrate,
wherein the serializer is disposed to be overlapped with the heat dissipation pad in the optical axis direction.

21. The camera module according to claim 17,
wherein the first substrate comprises a first layer being disposed with the image sensor, a second layer being embedded with the serializer, and a third layer being disposed with the heat dissipation pad, and
wherein the second layer is disposed between the first layer and the third layer.

22. The camera module according to claim 21, comprising:
a resistor being embedded inside the second layer of the first substrate.

23. The camera module according to claim 22,
wherein an adhesive member is applied to one surface and the other surface of the second layer.

24. The camera module according to claim 17, comprising:
a bump being formed on a lower surface of the image sensor,
wherein the bump is bonded to the substrate.

25. The camera module according to claim 24,
wherein an adhesive member is applied to a certain space formed between the image sensor and the substrate.

26. The camera module according to claim 17,
wherein the image sensor is one image sensor among a plurality of types of image sensors, and
wherein a pin is formed at a position corresponding to a connecting terminal configured with one pin map on one surface of the substrate.
